(19) United States
(12) Patent Application Publication
(10) Pub. No.: US 2025/0226339 A1
(43) Pub. Date: Jul. 10, 2025

(54) ADVANCED SEMICONDUCTOR PACKAGING STRUCTURE

(71) Applicant: AMAZING COOL TECHNOLOGY CORPORATION, Taipei City (TW)

(72) Inventors: Hsien-Tsung Tsai, Hsinchu City (TW); Yang-Ming Shih, Taichung City (TW); Hung-Yun Hsu, Hsinchu County (TW)

(73) Assignee: AMAZING COOL TECHNOLOGY CORPORATION, Taipei City (TW)

(21) Appl. No.: 18/946,871

(22) Filed: Nov. 13, 2024

(30) Foreign Application Priority Data
Jan. 5, 2024 (TW) 113100623

(51) Int. Cl. H01L 23/00; H01L 25/065; H10B 80/00

(52) U.S. Cl. CPC H01L 24/05; H01L 24/08; H01L 25/0657; H01L 2224/05647; H01L 2224/05693; H01L 2224/08146; H01L 2225/06541; H01L 2225/06568; H10B 80/00

(57) ABSTRACT

An advanced semiconductor packaging structure includes a circuit board, a first chip disposed on the circuit board, and a second chip disposed on the first chip. The first chip has solder balls arranged at intervals and bonded to the circuit board, and first pads arranged at intervals. The second chip has second pads arranged at intervals. Each of the second pads is correspondingly bonded to each of the first pads. Each of the first and second pads comprises a graphene-copper composite material composed of graphene and copper. The graphene has a plurality of graphene microfilms. The graphene microfilms are dispersed and arranged in the gaps between adjacent copper atoms. The graphene microfilms have covalent bonds. Based on the total weight of the graphene-copper composite material, the graphene content is less than 3 wt %, and the oxygen content in the graphene-copper composite material is not greater than 10 ppm.

### BACKGROUND OF THE INVENTION

### 1. Field of the Invention

The present disclosure relates to a semiconductor packaging structure, particularly a type of advanced semiconductor packaging structure.

### 2. Description of the Prior Art

The size of semiconductor devices has been decreasing year by year following Moore's Law, leading to continuous advancements in advanced integrated circuit (IC) manufacturing processes. However, with the increasing demand for advanced semiconductor devices, traditional packaging technologies can no longer meet the needs of advanced semiconductor devices obtained through advanced IC processes. Therefore, the demand for advanced packaging technologies such as chip-on-wafer (CoW) and chip-on-wafer-on-substrate (CoWoS) has also increased accordingly.

FIG. 1 illustrates a conventional semiconductor packaging structure 1, which includes a circuit board 11, a lower chip 12 disposed on the circuit board 11, and an upper chip 13 bonded to the lower chip 12. Solder balls 111 are disposed below the circuit board 11 with intervals between them. An internal circuit line (not shown) of the circuit board 11 is electrically connected to an external circuit through the solder balls 111.

The lower chip 12 includes a lower silicon substrate 121, a plurality of through-silicon vias (TSVs) 1210 arranged at intervals and penetrating the lower silicon substrate 121, a plurality of lower interconnections 122, a lower dielectric layer 123 formed on an upper surface of the lower silicon substrate 121 and having a plurality of lower pad openings 1230 arranged at intervals, a plurality of lower pads 124, and a plurality of solder balls 125 bonded to the circuit board 11. Each of the lower pad openings 1230 of the lower dielectric layer 123 corresponds to each of the TSVs 1210 of the lower silicon substrate 121, and each of the TSVs 1210 is correspondingly filled with each of the lower interconnections 122. Each of the lower pad openings 1230 of the lower dielectric layer 123 is correspondingly disposed with each of the lower pads 124.

The upper chip 13 includes an upper silicon substrate 130, a first upper dielectric layer 131, a second upper dielectric layer 132, a third upper dielectric layer 133, a packaging material 134, a plurality of upper interconnections 135, and a plurality of upper pads 136. The upper silicon substrate 130 has a lower half 1301 facing the lower chip 12 and an upper half 1302 facing away from the lower half 1301. The lower half 1301 of the upper silicon substrate 130 is divided into a working area 1303 and a dummy area 1304 by a trench 1300 penetrating the lower half 1301. The first upper dielectric layer 131 is formed on the lower surface of the working area 1303. The second upper dielectric layer 132 is formed on the lower surface of the first upper dielectric layer 131 and has a plurality of through holes 1320 arranged at intervals and penetrating the second upper dielectric layer 132. The third upper dielectric layer 133 is formed on the lower surface of the second upper dielectric layer 132 and has a plurality of upper pad openings 1330 arranged at intervals and penetrating the third upper dielectric layer 133. The packaging material 134 is filled in the trench 1300. Each of the upper interconnections 135 is correspondingly disposed in each of the through holes 1320. Each of the upper pads 136 is correspondingly disposed in each of the upper pad openings 1330 and is correspondingly bonded to each of the lower pads 124 of the lower chip 12.

Although the upper chip 13 can transmit the electronic signals generated by the working area 1303 during operation downward to the lower chip 12 through each of the upper pads 136 correspondingly bonded to each of the lower pads 124 of the lower chip 12, and transmit the electronic signals downward to the circuit board 11 through each of the lower interconnections 122 of the lower chip 12 to transmit the electronic signals to the outside, those skilled in the art know that the lower pads 124 and the upper pads 136 are generally made of copper (Cu) with a coefficient of thermal expansion (CTE) of 16.5 μm·m⁻¹·K⁻¹, and copper is easily oxidized at high temperatures during bonding, thereby increasing its resistance value. Since both the lower chip 12 and the upper chip 13 are advanced semiconductor devices manufactured by advanced IC processes, the process node has reached 28 nm or beyond, and the CTE of the lower dielectric layer 123 of the lower chip 12, the first upper dielectric layer 131, the second upper dielectric layer 132, the third upper dielectric layer 133, and the packaging material 134 of the upper chip 13 is significantly different from that of copper. Therefore, in the manufacturing process of the conventional semiconductor packaging structure 1, the process yield and the stability of the component in operation are affected due to the large difference in the coefficient of thermal expansion, and interface resistance between each of the lower pads 124 and each of the upper pads 136 is increased due to the high temperature during bonding.

As described above, improving the advanced semiconductor packaging structure to solve problems such as reduced process yield and interface resistance is a task to be solved by relevant industries in the technical field.

### SUMMARY OF THE INVENTION

Therefore, the object of the present invention is to provide an advanced semiconductor packaging structure that can solve problems such as reduced process yield and interface resistance.

Accordingly, the advanced semiconductor packaging structure of the present invention includes a circuit board, a first chip, and a second chip.

The first chip includes a lower substrate disposed on the circuit board, a plurality of through-holes arranged at intervals and penetrating the lower substrate, a plurality of first interconnections, a dielectric layer formed on an upper surface of the lower substrate and having a plurality of lower openings arranged at intervals, a plurality of first pads, and a plurality of solder balls bonded to the circuit board. Each of the lower openings corresponds to each of the through-holes. Each of the first interconnections is correspondingly filled in each of the through-holes. Each of the first pads is correspondingly disposed in each of the lower openings, and a portion of the solder balls of the first chip is correspondingly bonded to each of the first interconnections.

The second chip includes an upper substrate having a lower part facing the first pads of the first chip, a first dielectric layer, a second dielectric layer, a third dielectric layer, a packaging material, a plurality of second interconnections, and a plurality of second pads. The lower part of the upper substrate is divided into a working area and a dummy area by a trench penetrating the lower part. The first dielectric layer is formed on the lower surface of the working area. The second dielectric layer is formed on the lower surface of the first dielectric layer and has a plurality of through-holes arranged at intervals and penetrating itself. The third dielectric layer is formed on the lower surface of the second dielectric layer and has a plurality of upper openings arranged at intervals and penetrating itself. Each of the through-holes corresponds to each of the upper openings. The packaging material is filled in the trench. Each of the second interconnections is correspondingly filled in each of the through-holes. Each of the second pads is correspondingly disposed in each of the upper openings and is correspondingly bonded to each of the first pads.

In the present invention, each of the first pads or each of the second pads comprises a graphene-copper composite material composed of graphene and copper. The graphene has a plurality of graphene microfilms. The graphene microfilms are dispersed and arranged in the gaps between adjacent copper atoms. The graphene microfilms have covalent bonds. Based on the total weight of the graphene-copper composite material, the graphene content is less than 3 wt %, and the oxygen content in the graphene-copper composite material is not greater than 10 ppm.

One effect of the present invention is that each of the first pads and second pads is made of a graphene-copper composite material that is not easily oxidized and has low resistance, which can solve the problems of interface resistance and reduced process yield caused by high-temperature bonding, and the graphene molecules in the graphene-copper composite material are dispersed and arranged in the gaps between copper atoms and bond with each other, which makes the advanced semiconductor packaging structure more stable in actual operation.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Other features and advantages of the present invention will be clearly presented in the detailed description of embodiments with reference to the drawings, wherein:

FIG. 1 is a schematic diagram illustrating a conventional advanced semiconductor packaging structure;

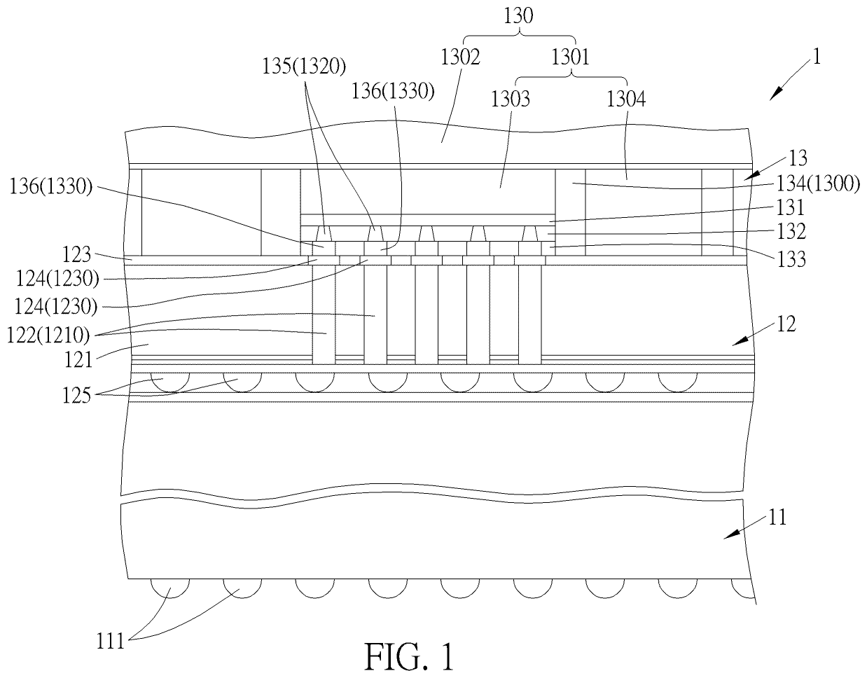

FIG. 2 is a schematic diagram illustrating an embodiment of the advanced semiconductor packaging structure of the present invention;

FIG. 3 is a schematic diagram illustrating an enlarged portion of an advanced semiconductor packaging structure according to another embodiment of the present invention; and

FIG. 4 is a schematic diagram showing an exemplary advanced semiconductor packaging structure according to still another embodiment of the present invention.

### DETAILED DESCRIPTION

In the following detailed description of embodiments of the invention, reference is made to the accompanying drawings, which form a part hereof, and in which is shown by way of illustration specific preferred embodiments in which the disclosure may be practiced. It is to be understood that similar elements are indicated by the same reference numerals in the following description.

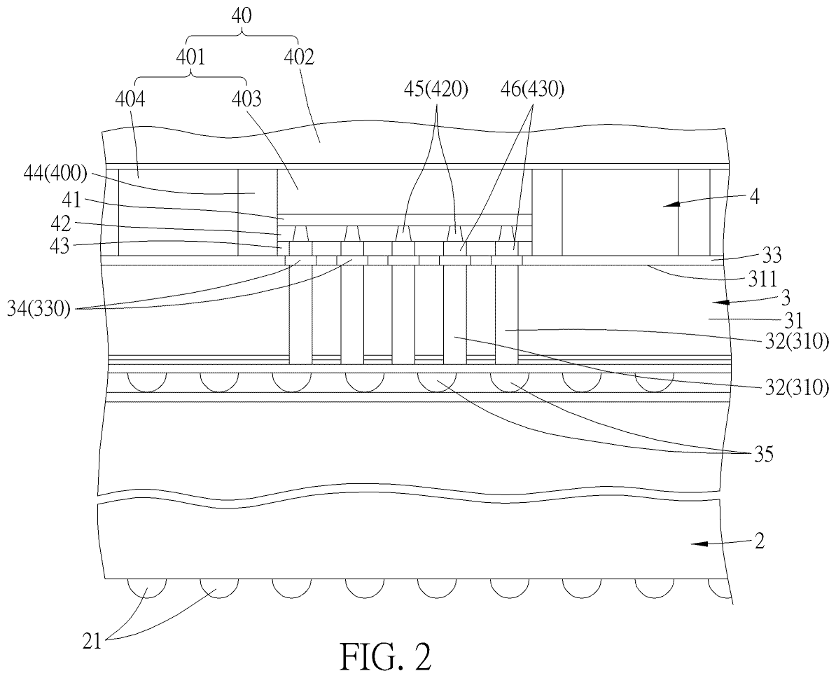

Referring to FIG. 2, an embodiment of the advanced semiconductor packaging structure of the present invention includes a circuit board 2, a first chip 3, and a second chip 4.

A circuit line (not shown) inside the circuit board 2 is electrically connected to the outside through a plurality of solder balls 21 bonded to the bottom of the circuit board 2.

The first chip 3 includes a lower substrate 31 disposed on the circuit board 2, a plurality of lower through-holes 310 arranged at intervals and penetrating the lower substrate 31, a plurality of first interconnections 32, a dielectric layer 33 formed on an upper surface 311 of the lower substrate 31 and having a plurality of lower openings 330 arranged at intervals, a plurality of first pads 34, and a plurality of solder balls 35 bonded to the circuit board 2. Each of the lower openings 330 corresponds to each of the lower through-holes 310. Each of the first interconnections 32 is correspondingly filled in each of the lower through-holes 310. Each of the first pads 34 is correspondingly disposed in each of the lower openings 330, and a portion of the solder balls 35 of the first chip 3 is correspondingly bonded to each of the first interconnections 32. In this embodiment of the invention, the lower substrate 31 and the solder balls 35 of the first chip 3 are exemplified by a silicon substrate and tin solder balls, respectively.

The second chip 4 includes an upper substrate 40 having a lower part 401 facing the first pads 34 of the first chip 3, a first dielectric layer 41, a second dielectric layer 42, a third dielectric layer 43, a packaging material 44, a plurality of second interconnections 45, and a plurality of second pads 46. The upper substrate 40 also has an upper part 402 facing away from the first chip 3, and the lower part 401 of the upper substrate 40 is divided into a working area 403 and a dummy area 404 by a trench 400 penetrating the lower part 401. The first dielectric layer 41 is formed on the lower surface of the working area 403. The second dielectric layer 42 is formed on the lower surface of the first dielectric layer 41 and has a plurality of through-holes 420 arranged at intervals and penetrating the second dielectric layer 42. The third dielectric layer 43 is formed on the lower surface of the second dielectric layer 42 and has a plurality of upper openings 430 arranged at intervals and penetrating the third dielectric layer 43. Each of the through-holes 420 corresponds to each of the upper openings 430. The packaging material 44 is filled in the trench 400. Each of the second interconnections 45 is correspondingly filled in each of the through-holes 420. Each of the second pads 46 is correspondingly disposed in each of the upper openings 430 and is correspondingly bonded to each of the first pads 34. In this embodiment of the invention, the upper substrate 40 is also exemplified by a silicon substrate.

In the present invention, each of the first pads 34 and each of the second pads 46 are made of a graphene-copper composite material composed of graphene and copper. The graphene includes a plurality of graphene microfilms. The graphene microfilms are dispersed and arranged in the gaps between adjacent copper atoms. The graphene microfilms are covalently bonded to each other. The graphene content is less than 3 wt % based on the total weight of the graphene-copper composite material, and the oxygen content in the graphene-copper composite material is not greater than 10 ppm.

In some embodiments of the present invention, the graphene content in the graphene-copper composite material is between 0.02 wt % and 0.5 wt %.

For example, the distance between each two adjacent first interconnections 32 of the first chip 3 is between 6 μm and 9 μm, and the size of each of the lower through-holes 310 of the lower substrate 31 of the first chip 3 is between 1.8 μm and 2.2 μm, and the size of each of the lower openings 330 of the dielectric layer 33 of the first chip 3 is between 3.3 μm and 3.7 μm. In addition, the distance between each two adjacent second interconnections 45 of the second chip 4 is between 6 μm and 9 μm, the size of each of the upper through-holes 420 of the second dielectric layer 42 of the second chip 4 is between 1.6 μm and 2.0 μm, and the size of each of the upper openings 430 of the third dielectric layer 43 of the second chip 4 is between 2.3 μm and 2.7 μm.

The method of manufacturing the graphene-copper composite material described above in the present invention is detailed as follows, including sequentially a step a, a step b, a step c, a step d, a step e, a step f, and a step g.

The step a is to provide a composition containing copper powder, modified graphene microfilms, and an adhesive. The adhesive suitable for this embodiment of the present invention contains 0.5 to 2.0 wt % of a coupling agent, 5 to 20 wt % of a dispersant, and a remainder of wax or a low molecular weight thermoplastic polymer. For example, the coupling agent can be selected from titanate or organic chromium compound. For example, the dispersant can be methyl cyclohexanol, polyacrylamide, or fatty acid polyethylene glycol ester. For example, the wax can be a general paraffin wax or microcrystalline wax. For example, the low molecular weight thermoplastic polymer can be acrylic. In addition, the modified graphene microfilms refer to graphene molecules in which at least one carbon atom is bonded to a functional group by an sp2 bond. Among them, the functional group is preferably a functional group containing oxygen and nitrogen atoms. The functional group suitable for the present invention is selected from fatty acids, such as stearic acid. It should be noted here that both titanate and organic chromium compounds have strong peripheral electron bonding forces. Therefore, the bonding strength between the graphene molecules and copper can be enhanced through the coupling agent. For example, titanate can have the advantage of being lightweight, and organic chromium compounds (organic chromium coordination compounds) can form more bonds due to their side chains. In addition, the dispersant and wax can effectively assist in the dispersion of the graphene microfilms and stabilize the dispersed graphene microfilms. In this embodiment of the present invention, the copper powder is MA-CC-S type copper powder purchased from Mitsui Kinzoku ACT Corporation of Japan; the modified graphene microfilms are P-PG20 type graphene purchased from EnerAge Inc.

The step b is to disperse the composition through planetary ball milling, so that the copper powder and graphene microfilms can be uniformly dispersed in the dispersant and wrapped by the wax to become a composite powder. Specifically, the stearic acid functional group linked to the graphene molecules of the modified graphene microfilms can cause the graphene microfilms to have the same charge, causing electrostatic repulsion between the graphene microfilms. Thereby, the graphene microfilms can be uniformly dispersed in the coupling agent, dispersant, and wax. In addition, the planetary ball milling method causes the modified graphene microfilms to generate heat due to friction, causing the sp3 bond of the stearic acid functional group linked to the graphene microfilms to break due to heat absorption. Therefore, the sp3 bond of the carbon atom that has been broken on the graphene microfilms can immediately rebond with the sp3 bond of the carbon atom that has been broken on other graphene microfilms, and simultaneously assisted by the coupling agent to assist the bonding between the broken graphene microfilms and the copper powder, so that the graphene microfilms are connected to each other in a planar shape and layer by layer wrapped around each copper powder to form the composite powder.

The step c is to heat the composite powder to become a liquid mixed raw material containing copper powder, graphene microfilms, and liquid adhesive.

The step d is to inject the liquid mixed raw material into a cold pressing mold and apply cold pressing to the liquid mixed raw material to solidify it into a green body.

The step e is to perform a debinding process on the green body under the condition of 140 to 170° C. using an inert gas as a fluid medium, thereby removing the adhesive in the green body and forming a debinding semi-finished product. Specifically, the temperature condition implemented in the debinding process can decompose and vaporize the adhesive in the green body, and the vaporized adhesive is brought out of the green body through the fluid medium to form the debinding semi-finished product.

The step f is to sinter the debinding semi-finished product at a temperature of 1050° C. in a nitrogen or hydrogen atmosphere for 1 hour, so that the copper powder in the debinding semi-finished product melts and combines with each other to become a copper body, and the graphene microfilms in the debinding semi-finished product are dispersed in the copper body to become a graphene-copper composite material semi-finished product. It should be supplemented here that since the carbon atoms between the graphene molecules are arranged in a honeycomb-shaped lattice arrangement through their own SP2 hybrid orbitals, they exhibit a two-dimensional structure. Therefore, after sintering, the graphene molecules will be dispersed and arranged in the gaps between the copper atoms in the copper lattice, and will bond with each other, which can improve the high stability of the graphene-copper composite material semi-finished product.

The step g is to apply vacuum smelting at 1300° C. to the graphene-copper composite material semi-finished product under a nitrogen atmosphere to produce the graphene-copper composite material of this embodiment of the invention. It should be supplemented here that, considering that after planetary ball milling, the graphene molecules that have not formed bonds with other graphene molecules or copper atoms are distributed more randomly in the graphene-copper composite material semi-finished product after the sintering process is completed. Therefore, through vacuum smelting, the graphene-copper composite material semi-finished product can be melted into a copper melt containing graphene microfilms, so that the graphene microfilms can be uniformly dispersed in the copper melt. In addition, since the surface of the copper powder is easily oxidized into copper oxide, the vacuum smelting process in step g can further reduce the copper oxide, so that the oxygen content in the graphene-copper composite material is reduced to not greater than 10 ppm.

After completing the vacuum smelting process of step g in the present invention, the graphene-copper composite material of this embodiment is analyzed by an oxygen-nitrogen-hydrogen analyzer, model EMGA 930, according to the ASTM E 2575-19 standard specification, showing that its oxygen content is only 6.0 ppm. In addition, the graphene-copper composite material has a thermal conductivity of not less than 460 W/mK.

Specifically, this embodiment of the present invention uses the graphene-copper composite material as a cathode target for a sputtering apparatus. Therefore, each of the first pads 34 of the first chip 3 and each of the second pads 46 of the second chip 4 are obtained by sputtering from the cathode target of the sputtering apparatus. In some embodiments, the first pad 34 of the first chip 3 and the second pad 46 of the second chip 4 are copper pads, and a thin layer of graphene-metal composite material is sputtered onto a surface of either the first pad 34 of the first chip 3 or the second pad 46 of the second chip 4.

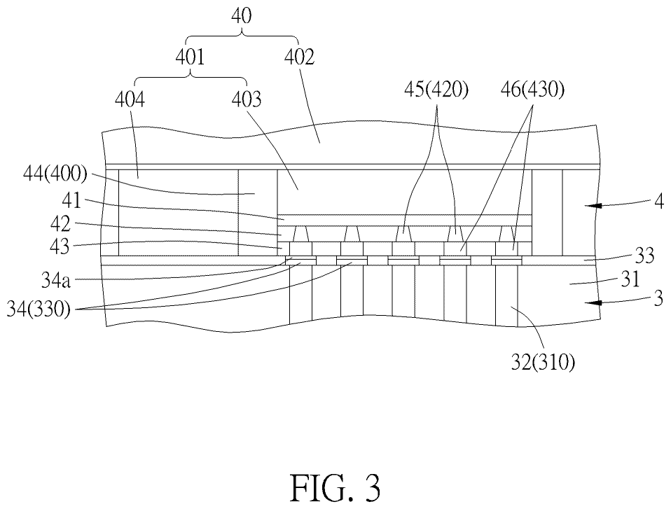

FIG. 3 is a schematic diagram illustrating an enlarged portion of an advanced semiconductor packaging structure according to another embodiment of the present invention, wherein like regions, layers or materials are designated by like numeral numbers or labels. As shown in FIG. 3, the first pads 34 and the second pads 46 are composed of copper. On each of the first pads 34, a graphene-metal composite material layer 34a composed of graphene and a metal element such as copper or silver is formed. The graphene includes a plurality of graphene microfilms. The graphene microfilms are dispersed and arranged in the gaps between adjacent copper atoms. The graphene microfilms are covalently bonded to each other. The graphene content is less than 3 wt % based on the total weight of the graphene-copper composite material, and the oxygen content in the graphene-metal composite material is not greater than 10 ppm. According to an embodiment of the invention, for example, the graphene-copper composite material layer 34a may have a thickness of equal to or less than 1.0 micrometer.

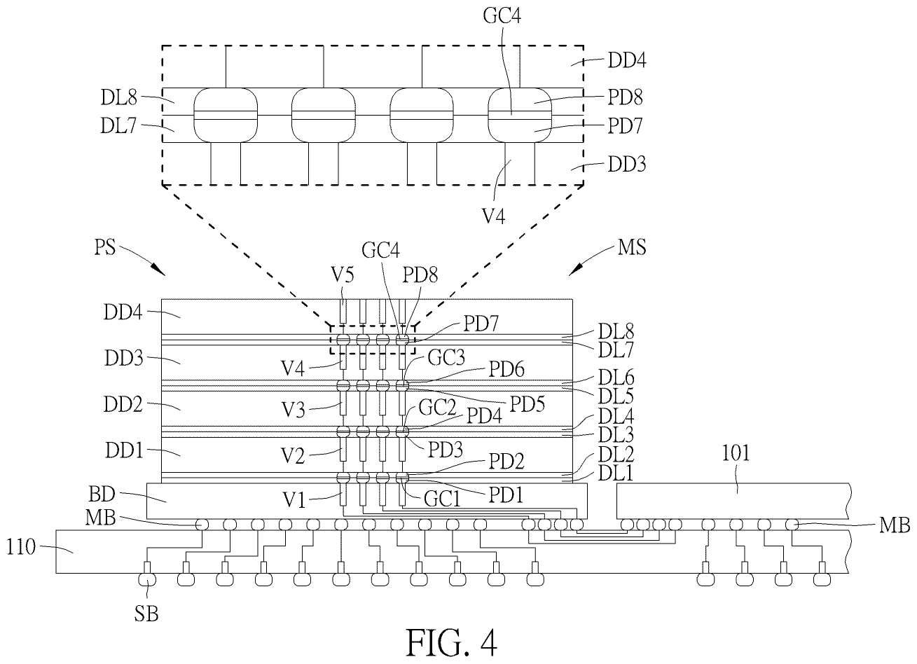

FIG. 4 is a schematic diagram showing an exemplary advanced semiconductor packaging structure according to still another embodiment of the present invention. FIG. 4 presents an exemplary HBM3 or HBM4 packaging structure that employs graphene-metal composite material (e.g., grapheme-copper composite) as the connection interface. This structure enhances the performance and reliability of the package by leveraging the excellent properties of the novel grapheme-metal composite material. For applications requiring high-performance computing and data processing, this packaging method is of significant importance.

As shown in FIG. 4, the advanced semiconductor packaging structure PS, which may be specifically designed for High Bandwidth Memory (HBM) packaging, at least comprises an interposer substrate 110, a memory stack MS mounted on the interposer substrate 110, and a processor die 101 mounted on the interposer substrate 110 in proximity to the memory stack MS. The memory stack MS and the processor die 101 are mounted on the interposer substrate 110 in a side-by-side manner. According to an embodiment, the interposer substrate 110 may be a circuit board or a silicon interposer, but is not limited thereto. According to an embodiment, the processor die 101 may comprise a central processing unit (CPU) die, a graphics processing unit (GPU) die, or a system-on-a-chip (SoC) die, but is not limited thereto.

According to an embodiment, the memory stack MS may comprise a plurality of dynamic random access memory (DRAM) dies DD1-DD4 stacked on top of one another and a base die BD that may include buffer circuitry and test logic. The base die BD may be mounted on the interposer substrate 110 through a plurality of micro bumps MB. A plurality of solder bumps SB may be provided on a lower surface of the interposer substrate 110. The memory stack MS may be connected to a memory controller on the processor die 101 through the interconnection fabricated in the interposer substrate 110. Within the memory stack MS, the DRAM dies DD1-DD4 are vertically interconnected by through-silicon vias (TSVs) V1-V5 as well as directly bonded copper pads PD1-PD8 with respective graphene-metal composite material interfaces GC1-GC4 formed therebetween. The copper pads PD1-PD8 may be formed in the bonding dielectric layers DL1-DL8, respectively. For example, the bonding dielectric layers DL1-DL8 may comprise silicon dioxide, silicon oxynitride or silicon carbide, but not limited thereto. For example, the graphene-metal composite material interfaces GC1-GC4 may be graphene-copper composite material interfaces. For example, as shown in the enlarged portion of FIG. 4, the DRAM die DD3 may be bonded to the DRAM die DD4 by using hybrid bonding. The bonding dielectric layer DL7 of the DRAM die DD3 is directly bonded to the bonding dielectric layer DL8 of the DRAM die DD4. The copper pad PD7 of the DRAM die DD3 is directly bonded to the copper pad PD8 of the DRAM die DD4 with graphene-copper composite material interface GC4 formed therebetween.

According to an embodiment, for example, the graphene-metal composite material interfaces GC1-GC4 may comprises grapheme and copper. The graphene has a plurality of graphene microfilms. The graphene microfilms are dispersed and arranged in gaps between adjacent copper atoms, and the graphene microfilms have covalent bonds, and based on a total weight of the graphene-copper composite material, the graphene content is less than 3 wt %, and the oxygen content in the graphene-copper composite material is not greater than 10 ppm. The graphene-metal composite material interfaces GC1-GC4 has a thermal conductivity of not less than 460 W/mK.

As can be seen from the detailed description of this embodiment of the present invention, the graphene-copper composite material has the characteristics of being difficult to oxidize, having low resistance (high conductivity), and having a low coefficient of thermal expansion. Therefore, it is preliminarily inferred that this embodiment of the present invention can solve the interface resistance problem caused by high-temperature bonding between each of the first pads 34 of the first chip 3 and each of the second pads 46 of the second chip 4, and can also solve the problem of reduced process yield. In addition, the graphene molecules in the graphene-copper composite material are dispersed and arranged in the gaps between the copper atoms in the copper lattice, and bond with each other. Therefore, the stability of the graphene-copper composite material is high, leading to good stability of the advanced semiconductor packaging structure of this embodiment of the present invention in actual operation.

In order to verify that this embodiment of the present invention uses the graphene-copper composite material to replace the lower pads 125 and upper pads 136 (that is, copper) mentioned in the prior art to solve the interface resistance problem caused by high-temperature bonding, the applicant conducted electrical tests on the graphene-copper foil made from the traditional copper foil (model C1100) and the graphene-copper composite material before and after high-temperature bonding.

Specifically, the applicant first stacked two insulating blocks and three C1100 copper foils (length, width, and thickness were 50 cm, 6 cm, and 200 μm, respectively) in turn, then welded the opposite two ends of the three C1100 copper foils at a temperature of 900° C. (welding area was 6 cm*6 cm) to become a comparative sample, and then conducted an electrical test on the comparative sample after high-temperature bonding. It is noteworthy that before welding, each C1100 copper foil was subjected to an electrical test before high-temperature bonding. In addition, the three graphene-copper foils made from the graphene-copper composite material were also welded into an experimental sample under the same conditions as the comparative sample, and then electrical tests were conducted on the experimental sample before and after high-temperature bonding. The electrical test results of the comparative sample and the experimental sample before and after high-temperature bonding are summarized in Table 1 below.

TABLE 1

| | Comparison | Experimental | Resistance |
|---|---|---|---|
| Sample | Sample | Sample | Drop (%) |
| Single Actual Resistance (μΩ) | 0.70 | 0.6609 | 7 |
| | 0.71 | 0.6449 | |
| | 0.70 | 0.6597 | |
| Theoretical Resistance of | 0.235 | 0.2194 | 6.6 |
| Parallel Connection (μΩ) | | | |
| Actual Resistance after Welding | 0.9 | 0.2129 | 76 |
| (μΩ) | | | |

As shown in Table 1 above, the actual resistance measured before high-temperature bonding (welding) of the three C1100 copper foils in the comparative sample was between 0.70 and 0.71 μΩ, while the actual resistance measured before high-temperature bonding (welding) of the three graphene-copper foils in the experimental sample was between 0.65 and 0.66 μΩ (resistance decreased by about 7%). The actual resistance measured before high-temperature bonding (welding) of the three C1100 copper foils in the comparative sample was calculated to be 0.235 μΩ when connected in parallel, while the actual resistance measured before high-temperature bonding (welding) of the three graphene-copper foils in the experimental sample was calculated to be 0.2194 μΩ when connected in parallel (resistance decreased by about 6.6%). The actual resistance measured after high-temperature (900° C.) bonding/welding of the three C1100 copper foils in the comparative sample reached 0.9 μΩ, which was much higher than its theoretical calculated value (0.235 μΩ). On the other hand, the actual resistance measured after high-temperature (900° C.) bonding/welding of the three graphene-copper foils in the experimental sample was only 0.2129 μΩ, close to its theoretical calculated value (0.2194 μΩ), and decreased by about 76% compared to the comparative sample. This proves that using the graphene-copper composite material to replace the lower pads 125 and upper pads 136 (that is, copper) mentioned in the prior art, as used in each of the first pads 34 and second pads 46 of this embodiment of the present invention, can indeed solve the interface resistance problem caused by high-temperature bonding.

In summary, each of the first pads 34 and second pads 46 of the advanced semiconductor packaging structure of the present invention is made of a graphene-copper composite material that is difficult to oxidize, has low resistance, and has a low coefficient of thermal expansion, which can solve the interface resistance and reduced process yield problems caused by high-temperature bonding. Moreover, the graphene molecules in the graphene-copper composite material are dispersed and arranged in the gaps between the copper atoms in the copper lattice, and bond with each other, making the advanced semiconductor packaging structure stable in actual operation. Therefore, the present invention can indeed achieve its purpose.

However, the foregoing is merely an embodiment of the present invention, and should not be used to limit the scope of the implementation of the present invention. Any simple equivalent changes and modifications made based on the scope of the patent application and the content of the patent specification are still within the scope of the patent coverage of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor packaging structure, comprising:
a circuit board;
a first chip, comprising a lower substrate disposed on the circuit board, a plurality of through-holes arranged at intervals and penetrating the lower substrate, a plurality of first interconnections, a dielectric layer formed on an upper surface of the lower substrate and having a plurality of lower openings arranged at intervals, a plurality of first pads, and a plurality of solder balls bonded to the circuit board, wherein each of the lower openings corresponds to each of the through-holes, each of the first interconnections is correspondingly filled in each of the through-holes, each of the first pads is correspondingly disposed in each of the lower openings, and a portion of the solder balls of the first chip is correspondingly bonded to each of the first interconnections; and
a second chip, comprising an upper substrate having a lower part facing the first pads of the first chip, a first dielectric layer, a second dielectric layer, a third dielectric layer, a packaging material, a plurality of second interconnections, and a plurality of second pads, wherein the lower part of the upper substrate is divided into a working area and a dummy area by a trench penetrating the lower part, the first dielectric layer is formed on the lower surface of the working area, the second dielectric layer is formed on the lower surface of the first dielectric layer and has a plurality of through-holes arranged at intervals and penetrating the second dielectric layer, the third dielectric layer is formed on the lower surface of the second dielectric layer and has a plurality of upper openings arranged at intervals and penetrating the third dielectric layer, each of the through-holes corresponds to each of the upper openings, the packaging material is filled in the trench, each of the second interconnections is correspondingly filled in each of the through-holes, and each of the second pads is correspondingly disposed in each of the upper openings and is correspondingly bonded to each of the first pads;
wherein each of the first pads or each of the second pads comprises a graphene-copper composite material composed of graphene and copper; and wherein the graphene has a plurality of graphene microfilms, the graphene microfilms are dispersed and arranged in gaps between adjacent copper atoms, and the graphene microfilms have covalent bonds, and based on a total weight of the graphene-copper composite material, the graphene content is less than 3 wt %, and the oxygen content in the graphene-copper composite material is not greater than 10 ppm.

2. The semiconductor packaging structure according to claim 1, wherein the graphene-copper composite material has a thermal conductivity of not less than 460 W/mK.

3. The semiconductor packaging structure according to claim 1, wherein a distance between each two adjacent first interconnections is between 6 μm and 9 μm, and a distance between each two adjacent second interconnections is between 6 μm and 9 μm.

4. The semiconductor packaging structure according to claim 1, wherein a size of each of the lower through-holes of the lower substrate is between 1.8 μm and 2.2 μm, a size of each of the lower openings of the dielectric layer of the first chip is between 3.3 μm and 3.7 μm, a size of each of the upper through-holes of the second dielectric layer is between 1.6 μm and 2.0 μm, and a size of each of the upper openings of the third dielectric layer is between 2.3 μm and 2.7 μm.

5. A semiconductor packaging structure, comprising:
an interposer substrate;
a memory stack mounted on the interposer substrate; and
a processor die mounted on the interposer substrate in proximity to the memory stack, wherein the memory stack comprises a plurality of dynamic random access memory (DRAM) dies stacked on top of one another and a base die connected to the interposer substrate through a plurality of micro bumps, and wherein within the memory stack, the DRAM dies are vertically interconnected by through-silicon vias as well as directly bonded copper pads with respective graphene-metal composite material interfaces formed therebetween.

6. The semiconductor packaging structure according to claim 5, wherein the graphene-metal composite material interfaces comprises grapheme and copper.

7. The semiconductor packaging structure according to claim 6, wherein the graphene has a plurality of graphene microfilms, wherein the graphene microfilms are dispersed and arranged in gaps between adjacent copper atoms, and the graphene microfilms have covalent bonds, and based on a total weight of the graphene-copper composite material, the graphene content is less than 3 wt %, and the oxygen content in the graphene-metal composite material interfaces is not greater than 10 ppm.
